(19) United States
(12) Patent Application Publication
(10) Pub. No.: US 2026/0156850 A1
(43) Pub. Date: Jun. 4, 2026

(54) BIPOLAR TRANSISTOR STRUCTURES WITH SEMICONDUCTOR BASE FILM WITHIN ISOLATION LAYER, AND RELATED METHODS

(71) Applicant: GlobalFoundries U.S. Inc., Malta, NY (US)

(72) Inventors: Jacob M. DeAngelis, Burlington, VT (US); Steven M. Shank, Jericho, VT (US); Uppili S. Raghunathan, Essex Junction, VT (US); Cameron Luce, Colchester, VT (US); Sarah A. McTaggart, Essex Junction, VT (US); Megan Elizabeth Lydon-Nuhfer, Essex Junction, VT (US)

(21) Appl. No.: 18/967,735

(22) Filed: Dec. 4, 2024

(51) Int. Cl. H10D 10/80; H10D 10/01; H10D 62/10; H10D 62/13; H10D 62/17

(52) U.S. Cl. CPC H10D 10/821; H10D 10/021; H10D 62/115; H10D 62/136; H10D 62/137; H10D 62/177

(57) ABSTRACT

The disclosure provides bipolar transistor structures with a semiconductor base film within an opening of an isolation layer, and related methods. A structure according to the disclosure includes a semiconductor base film on a collector terminal. The semiconductor base film includes a first portion within an opening of an isolation layer. The first portion includes an intrinsic semiconductor. A second portion of the semiconductor base film is on the first portion. The second portion includes a sidewall adjacent the isolation layer and a lower surface on the isolation layer. A semiconductor film is on an upper surface of the first portion of the isolation layer and adjacent a sidewall of the second portion of the isolation layer. An emitter is on the semiconductor film.

### BACKGROUND

The present disclosure relates to bipolar transistor structures and methods to form such structures.

Present technology is at atomic level scaling of certain micro-devices such as logic gates, bipolar transistors, field effect transistors (FETs), and capacitors. Circuit chips with millions of such devices are common. The structure of a bipolar transistor defines several of its properties during operation. Bipolar transistors typically include multiple materials within its base terminal, i.e., the terminal for controlling current flow between the emitter and collector terminals of the bipolar transistor. A base terminal includes a relatively high conductivity extrinsic base having a terminal thereto, and a relatively low conductivity intrinsic base connected to the extrinsic base and located between the emitter and collector. The number of mask levels and related processing steps to manufacture bipolar transistors according to conventional configurations can limit the cost effectiveness of bipolar transistors in high performance applications.

### SUMMARY

The illustrative aspects of the present disclosure are designed to solve the problems herein described and/or other problems not discussed.

Embodiments of the disclosure provide a structure including: a semiconductor base film on a collector terminal, the semiconductor base film including: a first portion within an opening of an isolation layer, the first portion including an intrinsic semiconductor, and a second portion on the first portion, the second portion including a sidewall adjacent the isolation layer and a lower surface on the isolation layer; a semiconductor film on an upper surface of the first portion of the isolation layer and adjacent a sidewall of the second portion of the isolation layer; and an emitter on the semiconductor film.

Other embodiments of the disclosure provide a structure including: an isolation stack including a first isolation layer having a first opening and a second isolation layer having a second opening over the first opening, wherein a width of the first opening is larger than a width of the second opening; a collector terminal on a subcollector and within the first opening of the first isolation layer; a semiconductor base film on the collector terminal, the semiconductor base film including: a first portion within the second opening of the second isolation layer, the first portion including an intrinsic semiconductor, and a second portion on the first portion, the second portion including a sidewall adjacent the isolation layer and a lower surface on the isolation layer; a semiconductor film on an upper surface of the first portion of the isolation layer and adjacent a sidewall of the second portion of the isolation layer; and an emitter on the semiconductor film.

Additional embodiments of the disclosure provide a method including: forming a semiconductor base film on a collector terminal, the semiconductor base film including: a first portion within an opening of an isolation layer, the first portion including an intrinsic semiconductor, and a second portion on the first portion, the second portion including a sidewall adjacent the isolation layer and a lower surface on the isolation layer; forming a semiconductor film on an upper surface of the first portion of the isolation layer and adjacent a sidewall of the second portion of the isolation layer; and forming an emitter on the semiconductor film.

### BRIEF DESCRIPTION OF THE DRAWINGS

These and other features of this disclosure will be more readily understood from the following detailed description of the various aspects of the disclosure taken in conjunction with the accompanying drawings that depict various embodiments of the disclosure, in which:

FIG. 1 depicts a cross-sectional view in plane X-Z of a structure according to embodiments of the disclosure.

FIG. 2 depicts a cross-sectional view in plane X-Z of a structure according to further embodiments of the disclosure.

FIG. 3 depicts a cross-sectional view in plane X-Z of a structure according to additional embodiments of the disclosure.

FIGS. 4-10 depict cross-sectional views in plane X-Z of methods to form a structure according to embodiments of the disclosure.

It is noted that the drawings of the disclosure are not necessarily to scale. The drawings are intended to depict only typical aspects of the disclosure, and therefore should not be considered as limiting the scope of the disclosure. In the drawings, like numbering represents like elements between the drawings.

### DETAILED DESCRIPTION

In the following description, reference is made to the accompanying drawings that form a part thereof, and in which is shown by way of illustration specific illustrative embodiments in which the present teachings may be practiced. These embodiments are described in sufficient detail to enable those skilled in the art to practice the present teachings, and it is to be understood that other embodiments may be used and that changes may be made without departing from the scope of the present teachings. The following description is, therefore, merely illustrative.

It will be understood that when an element such as a layer, region, or substrate is referred to as being “on” or “over” another element, it may be directly on the other element or intervening elements may also be present. In contrast, when an element is referred to as being “directly on” or “directly over” another element, there may be no intervening elements present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

Reference in the specification to “one embodiment” or “an embodiment” of the present disclosure, as well as other variations thereof, means that a particular feature, structure, characteristic, and so forth described in connection with the embodiment is included in at least one embodiment of the present disclosure. Thus, the phrases “in one embodiment” or “in an embodiment,” as well as any other variations appearing in various places throughout the specification are not necessarily all referring to the same embodiment. It is to be appreciated that the use of any of the following “/,” “and/or,” and “at least one of,” for example, in the cases of “A/B,” “A and/or B” and “at least one of A and B,” is intended to encompass the selection of the first listed option (a) only, or the selection of the second listed option (B) only, or the selection of both options (A and B). As a further example, in the cases of “A, B, and/or C” and “at least one of A, B, and C,” such phrasing is intended to encompass the first listed option (A) only, or the selection of the second listed option (B) only, or the selection of the third listed option (C) only, or the selection of the first and the second listed options (A and B), or the selection of the first and third listed options (A and C) only, or the selection of the second and third listed options (B and C) only, or the selection of all three options (A and B and C). This may be extended, as readily apparent by one of ordinary skill in the art, for as many items listed.

The disclosure provides bipolar transistor structures with a semiconductor base film within an opening of an isolation layer, and related methods. A structure according to the disclosure includes a semiconductor base film on a collector terminal. The semiconductor base film includes a first portion within an opening of an isolation layer. The first portion includes an intrinsic semiconductor. A second portion of the semiconductor base film is on the first portion. The second portion includes a sidewall adjacent the isolation layer and a lower surface on the isolation layer. A semiconductor film is on an upper surface of the first portion of the isolation layer and adjacent a sidewall of the second portion of the isolation layer. An emitter is on the semiconductor film.

Bipolar junction transistor (BJT or simply ‘BT’) structures, such as those in embodiments of the disclosure, operate using multiple “P-N junctions.” The term “P-N” refers to two adjacent materials having different types of conductivity (i.e., P-type and N-type), which may be induced through dopants within the adjacent material(s). A P-N junction, when formed in a device, may operate as a diode. A diode is a two-terminal element, which behaves differently from conductive or insulative materials between two points of electrical contact. Specifically, a diode provides high conductivity from one contact to the other in one voltage bias direction (i.e., the “forward” direction), but provides little to no conductivity in the opposite direction (i.e., the “reverse” direction). In the case of the P-N junction, the orientation of a diode's forward and reverse directions may be contingent on the type and magnitude of bias applied to the material composition of one or both terminals, which affects the size of the potential barrier. In the case of a junction between two semiconductor materials, the potential barrier will be formed along the interface between the two semiconductor materials. Generally, a BJT structure includes a base region vertically or horizontally between emitter and collector materials. A BJT can be either a PNP-type BJT or an NPN-type BJT. In a PNP-type BJT, the emitter and collector regions have P-type conductivity and at least a portion of the base region has N-type conductivity. In an NPN-type BJT, the emitter and collector regions have N-type conductivity and at least a portion of the base has P-type conductivity.

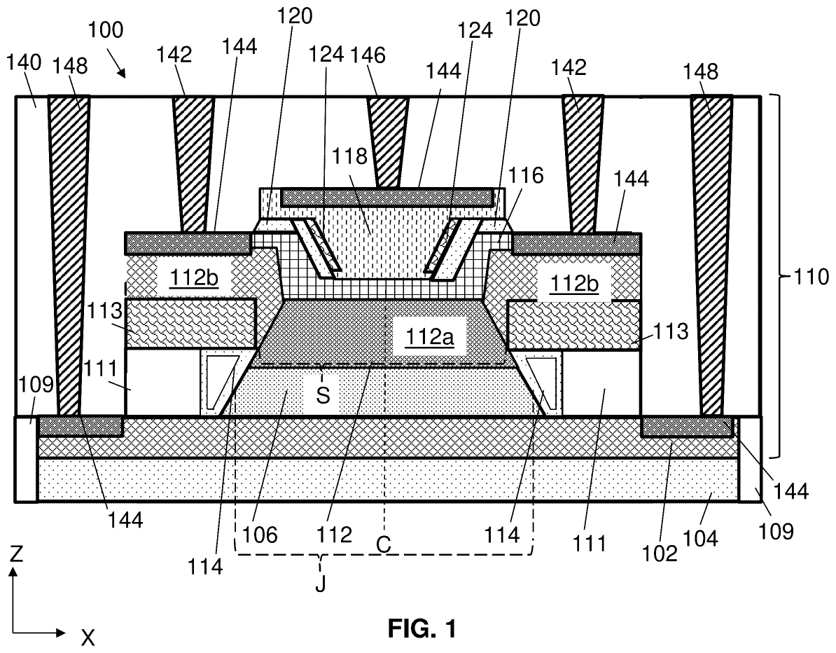

Referring to FIG. 1, a structure 100 according to the disclosure may include a bipolar transistor 110 (e.g., a vertically oriented bipolar transistor as discussed herein) with a semiconductor base film (simply “base film” hereafter) 112 located within an opening of an isolation stack (e.g., an assembly of first isolation layer 111 and/or second isolation layer 113, discussed herein), and including a first lightly doped or undoped (“intrinsic”) portion and a second highly doped (“extrinsic”) portion. Base film 112 is structurally continuous but includes a crystal plane facet separating the first portion from the second portion. As discussed in further detail herein, the first (lower) portion of base film 112 may include a monocrystalline semiconductor whereas the second (upper) portion of base film 112 may include a polycrystalline semiconductor. The second portion of base film 112 includes a sidewall adjacent isolation layer(s) 111, 113 and a lower surface on isolation layer(s) 111, 113. In this configuration, base film 112 includes a first portion recessed within isolation layer(s) 111, 113. Structure 100 may be formed on a subcollector 102 (i.e., a doped portion of a semiconductor substrate) including, e.g., one or more monocrystalline semiconductor materials. Subcollector 102 may include but is not limited to silicon, germanium, silicon germanium (SiGe), silicon carbide, or any other common IC semiconductor substrates. In the case of SiGe, the germanium concentration in subcollector 102 may differ from other SiGe-based structures described herein. A portion or entirety of subcollector 102 may be strained. Subcollector 102 may be doped (i.e., it may define a “doped well”) , e.g., to enable coupling to the lower active semiconductor materials of a vertical bipolar transistor. Subcollector 102 may have any conceivable doping type and/or doping composition appropriate for use within and/or coupling to the collector terminal of a bipolar transistor. For instance, subcollector 102 may have the same dopant type as a collector terminal (simply “collector” hereafter) 106 formed thereon, e.g., P-type doping in the case of a PNP-type BJT or N-type doping in the case of an NPN-type BJT, and/or may have a higher or lower dopant concentration therein.

As second isolation layer 113 is formed, e.g., by deposition on vacant spaces, limited space between collector 106 and first isolation layer 111 may prevent second isolation layer 113 material from completely filling an underlying space horizontally between collector 106 and first isolation layer 111. Remaining space below second isolation layer 113, not filled by collector 106, first isolation layer 113, or other semiconductive or conductive materials, may form an air gap 114 horizontally between collector 106 and first isolation layer 111. In other implementations, portions of first isolation layer 111 may be removed (e.g., it may be undercut during etching as discussed herein) to form air gap 114 before collector 106 and base film 112 are formed on subcollector 102.

Air gap 114 refers to a region of space surrounded by, and hence not filled with, solid materials such as collector 106, first isolation layer 111, second isolation layer 113, etc. Air gap 114 may be formed by any conceivable method to enclose and/or seal off a desired space to prevent additional materials from being formed therein. For instance, the horizontal space between a base film 112 and second isolation layer 113 may be significantly less than that of the horizontal space between collector 106 and first isolation layer 111. By forming second isolation layer 113 on first isolation layer 111 (e.g., by conformal deposition and/or other processing techniques described herein), second isolation layer 113 will extend horizontally to the horizontal edge of base film 112 without entering the space between collector 106 and first isolation layer 111. Air gap 114, alternatively known as a “cavity,” “gas dielectric,” and/or similar terms known in the art, thus may have a lower dielectric constant (i.e., it is less conductive) than nearby insulative materials such as isolation layers 111, 113. Air gap 114 thus may be formed by any currently known or later developed process to create an insulative region of space not filled with dielectric materials and/or other components.

Air gap 114 may have a substantially triangular shape, e.g., where collector 106 and base film 112 have sloped sidewalls but first isolation layer 111 has a vertical sidewall. Air gap 114 may take on different shapes, depending on the shape of collector 106 and base film 112. In this case, at least a portion of collector 106 is horizontally distal to first isolation layer 111 and beneath any undercut portion(s) of second isolation layer 113 and may feature a sloped sidewall. Base film 112 on collector 106 also may include a sloped sidewall adjacent and/or below air gap 114, e.g., in cases where base film 112 is formed by epitaxial growth or otherwise formed selectively on collector 106. Air gap 114 may be desirable as further contributing to electrical isolation between base film 112 and collector 106. Air gap 114 in particular may impede or prevent other physical interfaces from forming between second portion(s) 112b of base film 112 and materials other than semiconductor film 116. In some implementations (e.g., where isolation layers 111, 113 are formed through various other currently known or later developed techniques), air gap 114 instead may be bounded by portions of base film 112 and/or second isolation layer 113, or simply may not be present.

Collector 106 may be on subcollector 102, e.g., as a single layer or multiple similarly doped but distinct layers formed by epitaxial deposition of silicon, SiGe, and/or other semiconductor materials on subcollector 102 and may have a predetermined doping type, e.g., by being doped in-situ or during formation of semiconductor material(s) of subcollector 102 and/or subcollector 102. Collector 106 is monocrystalline in structure. Collector 106 may define active semiconductor material of a vertical bipolar transistor, and thus may be vertically below other terminals (i.e., intrinsic base, extrinsic base, and emitter terminals discussed herein) of bipolar transistor 110. Collector 106 is illustrated as having tapered (i.e., inwardly diagonally slanted) sidewalls over subcollector 102, e.g., as a result of being formed by epitaxial deposition and growth. However, collector 106 may have other shapes as a result of varying manufacturing techniques.

One or more trench isolations 109 may be on, or within, portions of substrate 104 for vertical electrical isolation of active semiconductor materials (e.g., subcollector 102) on substrate 104 from other materials within bipolar transistor 110, and/or for horizontally separating different active materials within substrate 104 from each other. As shown, trench isolations 109 may extend vertically into substrate 104. Various trench isolations 109 may extend horizontally over substrate 104 as a single layer and may be horizontally adjacent subcollector 102.

Structure 100 also may include a first isolation layer 111 to prevent electrical shorting between subcollector 102 and overlying areas of bipolar transistor 110. Portions of first isolation layer 111 may be removed to form an opening J, which may undercut certain remaining portions of first isolation layer 113. Opening J within first isolation layer 111 may form substantially triangular divots, recesses, etc., where collector 106 material may be grown. Thus, collector 106 when formed may have a tapered or sloped shape, as shown.

A second isolation layer 113 may be on first isolation layer 111. Each isolation layer 111, 113 on subcollector 102 may have a respective composition, e.g., first isolation layer 111 may include one or more oxide based insulator materials whereas second isolation layer 113 may include one or more nitride based insulator materials (or vice versa). Each isolation layer 111, 113 also may include the same electrically insulative material(s). Either or both of isolation layer(s) 111, 113 may have the same composition as trench isolation 109. Isolation layer(s) 111, 113 and trench isolation 109 nonetheless constitute different components, e.g., due to their positions with respect to the various active components of structure 100. Isolation layer(s) 111, 113 may be formed by deposition and/or other techniques to provide electrically insulating materials on subcollector 102 and can then be etched back and planarized (e.g., using CMP). Such processing of second isolation layer 113 may create an opening S therein, which may have a larger width along the X-axis than opening J within first isolation layer 111. In addition, opening S within second isolation layer 113 may have vertically-oriented sidewalls whereas opening J within first isolation layer 113 may have substantially diagonal sidewalls.

Bipolar transistor 110 may include base film 112 (introduced as “semiconductor base film” previously herein) on collector 106. Base film 112 may include multiple crystallographic compositions, e.g., monocrystalline SiGe or any other monocrystalline semiconductor material that is doped to have a predetermined polarity in some areas and polycrystalline semiconductor material having similar or distinct doping in other areas. Different portions of base film 112 may have different amounts of doping, e.g., it may include intrinsically doped and extrinsically doped portions with relatively low and relatively high conductivity, respectively. Base film 112 may include a different semiconductor material (e.g., silicon germanium as opposed to silicon) than collector and 106 and an emitter terminal (simply “emitter” hereafter) 118 thereover. The use of differing semiconductor materials at the emitter-base junction and at the base-collector junction creates heterojunctions, which are, for example, suitable for handling higher frequencies. In this case, the BJT is referred to in the art as a heterojunction bipolar transistor (HBT). In the case where the bipolar transistor is an NPN-type transistor and subcollector 102, collector 106, and emitter 118 are doped n-type, base film 112 may be doped p-type to form a P-N junction, and hence a base-to-collector interface. It is also understood that base film 112 may be doped n-type in the case where the bipolar transistor is a PNP-type transistor. Regardless of doping profile, base film 112 may be formed using non-selective epitaxial growth and thus may include a first portion 112a within opening S and second portions 112b adjacent second isolation layer 113 and on upper surfaces of second isolation layer 113. In this configuration, second portions 112b encapsulate the sidewalls of second isolation layer 113 and overlie the horizontally outer ends of first portion 112a to extend horizontally beyond first portion 112b. Thus, portions 112a, 112b of base film 112 together define a substantial “U” shape.

Although first portion 112a may have the same composition as second portion 112b (i.e., semiconductor material(s) such as SiGe), it may have different crystallographic attributes and/or a distinct doping profile. First portion 112a of base film 112 in particular may be lightly doped, or possibly undoped, whereas second portion 112b of base film 112 may be doped more highly than first portion 112a. First portion 112a of base film 112 may be formed, e.g., by forming a layer of semiconductor material, which may be monocrystalline silicon or SiGe as discussed herein, on collector 106. Additional semiconductor material may be formed through non-selective epitaxial growth. Non-selective epitaxial growth of base film 112 material will cause the additional semiconductor material to be grown on all exposed surfaces of previously grown material and on adjacent materials regardless of composition. Thus, first portion 112a of base film 112 may be monocrystalline semiconductor and may have a similar geometrical profile to collector 106 thereunder. In the example of FIG. 1, collector 106 is trapezoidal and thus first portion 112a is also trapezoidal. The physical interface between first portion 112a and second portion(s) 112b of base film 112 may be substantially diagonal, e.g., it may be defined along a line extending inwardly diagonally upward from the upper surface of collector 106 toward the position of semiconductor film 116 (and emitter 118 thereover) above base film 112.

Continued forming of semiconductor material produces second portion 112b of base film 112 by non-selective epitaxial growth on adjacent sidewalls of second isolation layer 113, and on upper surfaces of second isolation layer 113. Second portion 112b, once formed, may be distinguished from first portion 112a by including a polycrystalline semiconductor composition, as well as having distinct conductive properties, and position relative to second isolation layer 113. In epitaxial growth, particularly non-selective epitaxial growth, the properties of the grown material will depend on the properties of the underlying material(s). Thus, any semiconductor material that is grown on second isolation layer 113 will have different properties from any semiconductor material that is grown on collector 106, despite such materials being grown at the same time and with the same or similar doping concentrations. Second portion 112b thus may include a polycrystalline semiconductor (e.g., polycrystalline SiGe) as compared to monocrystalline semiconductor (e.g., monocrystalline SiGe) in first portion 112a. The two types of materials will merge along a boundary therebetween, e.g., inwardly diagonally extending boundaries approximately midway between collector 106 and sidewalls of second isolation layer 113. Thus, portions 112a, 112b have different crystallographic properties due to being formed on different surfaces, despite being formed together (or perhaps simultaneously) via non-selective epitaxial deposition. It is understood that second portion 112b, by having a polycrystalline structure, is more conductive than monocrystalline material in first portion 112a.

Second isolation layer 113 may vertically separate second portion 112b of base film 112 from collector 106. In subsequent processing (e.g., after various materials discussed herein are formed on first portion 112a), second portion 112b optionally may be doped to have a substantially greater doping concentration and/or different conductivity type from first portion 112a. As discussed herein, second portion 112b may be doped p-type where bipolar transistor 110 is an NPN device or may be doped n-type in the case where bipolar transistor 110 is a PNP device. Portions 112a, 112b of base film 112 are shown with different cross-hatching to indicate their different crystal structure and/or doping concentrations, despite having the same or similar materials.

A semiconductor film 116 (e.g., a layer of crystalline silicon and/or other semiconductor having a different composition from base film 112) may be on each portion 112a, 112b of base film 112. Semiconductor film 116 may be grown, e.g., by non-selective deposition, epitaxial growth, etc., of silicon or similar semiconductor material(s) such that semiconductor film 116 is formed on upper surfaces and sidewalls of each portion 112a, 112b of base film 112. Semiconductor film 116 may be crystalline only where grown and/or in contact with the crystalline structure of first portion 112a, and polycrystalline structure on second portion 112b. Any portions of semiconductor film 116 not formed on base film 112 may be removed such that semiconductor film 116 is only on base film 112. Semiconductor film 116, in certain portions thereof, may have a similar conductivity and/or doping concentration as base film 112 but may include a different semiconductor material to function as an etch stop layer and/or intermediate material with varying dopants to enable forming of emitter 118 and/or spacer liners 120, 124 thereon in desired locations.

Semiconductor film 116 may have a substantially U-shaped geometry in the case where base film 112 thereunder is also U-shaped. Thus, portions of semiconductor film 116 include a valley above first portion 112a of base film 112 and substantially planar surfaces above second portions 112b of base film 112. This, in turn, allows self-alignment of emitter 118 with collector 106 and first portion 112a of base film 112 when emitter 118 is formed on base film 112. For instance, as shown, a centerline axis of emitter 118 may be substantially aligned with a centerline axis of opening S within isolation layer(s) 111, 113 such that all centerline axes are substantially coincident along line C (and/or in parallel with Z-axis). During operation, semiconductor film 116 may have a same or similar conductivity as base film 112 and thus semiconductor film 116, during operation, may be considered to be part of the base terminal for bipolar transistor 110.

Sidewalls and upper surfaces of semiconductor film 116 may have a first spacer liner 120 thereon. First spacer liner 120 may be vertically interposed between semiconductor film 116 and any portion(s) of emitter 118 thereover. First spacer liner(s) 120 may have the same composition, or a similar composition, as trench isolation(s) 109 discussed herein. Spacer liner(s) 120 may be present, e.g., to restrict the contact area between active material in emitter 118 and semiconductor film 116 to reduce the electrical resistance and/or parasitic losses between emitter 118 and both base film 112 and semiconductor film 116 during operation of bipolar transistor 110. First spacer liner 120 may be located, e.g., on sidewalls and uppermost surfaces of semiconductor film 116 without covering the lower interface between emitter 118 and semiconductor film 116. First spacer liner 120 may be formed in other positions and/or configurations, provided that some amount of contact area remains between emitter 118 and semiconductor film 116. In some implementations, first spacer liner 120 may be omitted entirely.

Bipolar transistor 110 also may include a set of second spacer liners 124 on sidewalls of first spacer liner 120. Second spacer liners 120 may have a similar composition to first spacer liner 120 or may be formed of a different material. For instance, second spacer liners 124 may be a nitride-based insulator whereas first spacer liner 120 may be an oxide-based insulator. Second (inner) spacer liner(s) 124 may be formed by conformal deposition on first spacer liner 120, and optionally, removing any portion second spacer liner(s) 124 on upper surfaces of first spacer liner 120 (e.g., by planarization) such that second spacer liner(s) 124 remain only on sidewalls of first spacer liner 120, and in some cases do not cover the entire sidewall of first spacer liner 120. Second spacer liners(s) 124, however formed, do not cover intended contact area between semiconductor film 116 and emitter 118. In some implementations, first spacer liner 120 and/or second spacer liners 124 may be combined into a single layer or may be part of a stack having more than two layers.

Emitter 118 may be on semiconductor film 116 and within first spacer liner 120 and second spacer liner 124. In this configuration, emitter 118 is vertically aligned with semiconductor film 116, first portion 112a (e.g., monocrystalline material) of base film 112, and collector 106. Emitter 118 also includes a lower portion horizontally between second portion(s) 112b (e.g., polycrystalline material) of base film 112 and semiconductor film 116 and may include an upper portion above upper surfaces of first spacer liner 120. Emitter 118 may have the same doping type as subcollector 102 and collector 106, and thus, has an opposite doping type relative to second portion(s) 112b (i.e., extrinsically doped portions) of base film 112. In the case where bipolar transistor 110 is an NPN device, collector 106 and emitter 118 may be doped n-type to provide the two n-type active semiconductor materials and portion(s) 112a, 112b of base film 112 (and semiconductor film 116 where applicable) may be doped p-type. Emitter 118 may include polycrystalline silicon and/or monocrystalline semiconductor materials, including one or more materials used elsewhere in structure 100 to form subcollector 102, collector 106, etc.

Structure 100 may include an inter-level dielectric (ILD) layer 140 over trench isolation 109, base film 112, semiconductor film 116, emitter 118, first spacer liner 120, second spacer liner 120, etc. ILD 140 may include the same insulating material as trench isolation 109 or may include a different electrically insulative material for vertically separating active materials from overlying materials, e.g., various horizontally extending wires or vias. ILD 140 and trench isolation 109 nonetheless constitute different components, e.g., due to trench isolation 109 being vertically between subcollector 102 and the various active components of structure 100. ILD 140 may be formed by deposition and/or other techniques to provide electrically insulating materials, and can then be planarized (e.g., using CMP), such that its upper surface remains above any active components formed on subcollector 102.

A set of base contacts 142 through ILD 140 may provide the vertical electrical coupling to second portion(s) 112b of base film 112 from overlying metal wires and/or vias. Base contacts 142, notably, do not extend to first portion 112a of base film 112 or semiconductor film 116. First portion 112a of base film 112 and semiconductor film 116 thus are coupled to base contacts 142 only through second portion(s) 112b. Some upper areas of second portion(s) 112b may be converted into a silicide layer 144 to improve conductivity between each base contact 142 and any portions of base film 112 thereunder, e.g., by providing a conductive metal such as cobalt (Co), titanium (Ti), nickel (Ni), platinum (Pt), or similar material on the upper surface(s) of a targeted material. The conductive material(s) may be annealed while in contact with the underlying semiconductor to produce silicide layer 144 for electrically coupling semiconductor materials to any contacts formed thereon. Excess conductive material can then be removed using any now known or later developed solution, e.g., etching.

Structure 100 also includes an emitter contact 146 to emitter 118 and one or more collector contacts 148 to collector 106 through subcollector 102. Each contact 146, 148 also may be coupled to emitter 118 or subcollector 102, respectively, through silicide layers 144 formed therein. Each contact 146 also may extend through ILD 140, thus connecting active semiconductor material within subcollector 102 or emitter 118 to overlying metal wires, vias, etc., above structure 100. Contact(s) 142, 146, 148 optionally may be formed as part of a single operation, e.g., by removing portions of ILD 140 to form openings, forming silicide layers 144 on semiconductor materials exposed within the openings, and filling the openings with metal to define each contact 142, 146, 148. One or more of contacts 142, 146, 148 may include refractory metal liners (not separately shown) on their sidewalls to impede or prevent electromigration degradation, shorting to other components, etc.

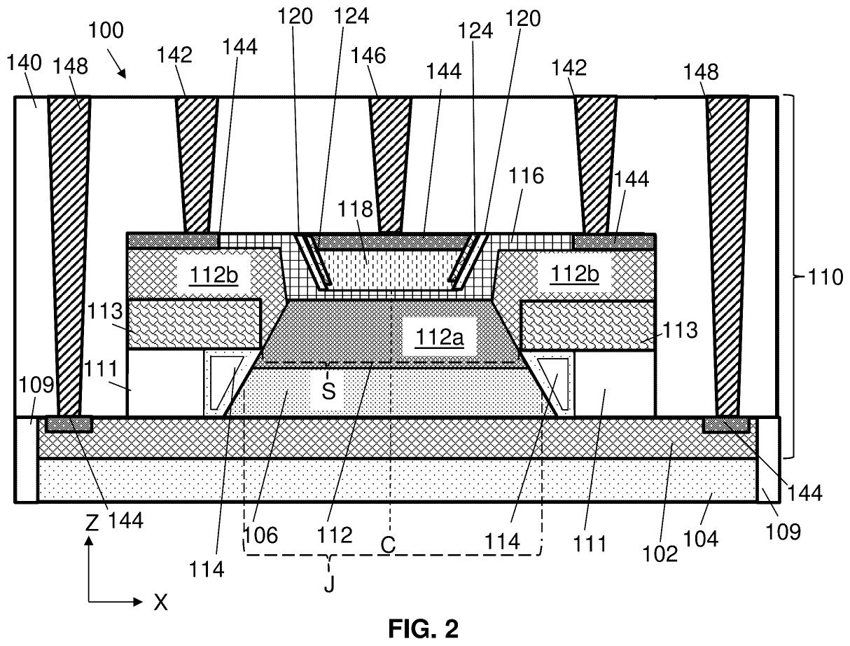

FIG. 2 depicts a further configuration of structure 100 in which the size of emitter 118, relative to base film 112 and semiconductor film 116, is smaller than in other implementations. In this case, emitter 118 and first spacer liner 120 may be etched and/or planarized before ILD 140 is formed thereover. The planarization of emitter 118 and first spacer liner 120 may be implemented by way of chemical mechanical planarization (CMP) or similar techniques. Etching and planarizing of emitter 118 and first spacer liner 120 may remove first spacer liner 120 from upper surfaces of semiconductor film 116, and/or may cause any remaining first spacer liner 120 to be present only along a sidewall boundary of semiconductor film 116 (e.g., horizontally between semiconductor film 116 and emitter 118, or second spacer liner 120 if present). The resulting implementation of structure 100 may feature silicide layer 144 for emitter 118 at substantially the same vertical position as silicide layers 144 for second portion 112b of base film 112, and/or with emitter contact 146 being approximately the same shape and size as base contact(s) 142. In all other respects, structure 100 and bipolar transistor 110 may be substantially unchanged from other implementations of structure 100.

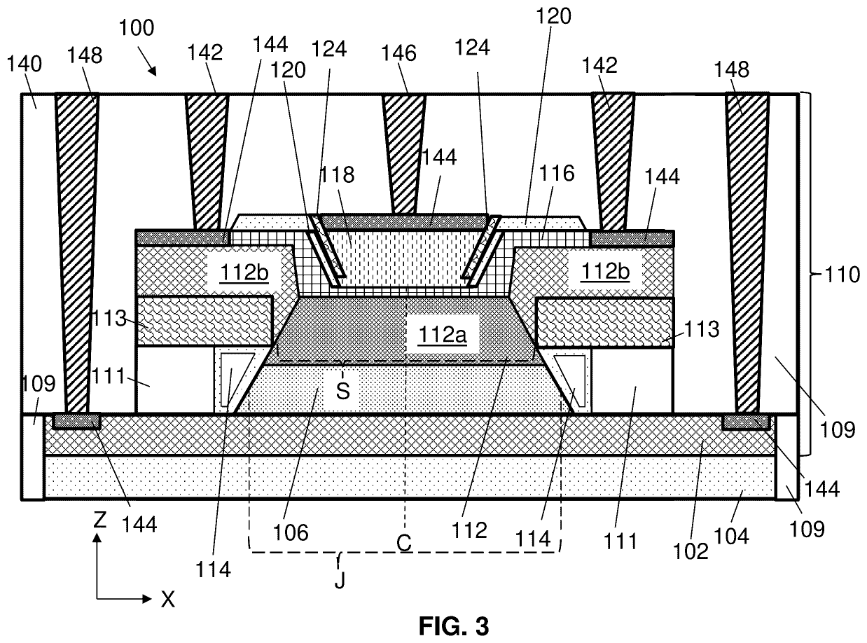

Referring now to FIG. 3, still further implementations of structure 100 may enable planarizing of emitter 118 without also removing adjacent portions of first spacer liner 120. To form structure 100 as shown in FIG. 3, a temporary mask (not shown) may be formed over bipolar transistor 110 to cover adjacent portions of base film 112, semiconductor film 116, and first spacer liner 120 thereon. With such a mask in place, emitter 118 can be planarized such that its upper surface is substantially coplanar with adjacent upper surfaces of first spacer liner 120. The temporary mask can then be removed, and remaining portions of structure 100 (e.g., ILD 140, contacts 146, 146, 148, etc.) can be formed such that emitter 118 and its silicide layer 144 extend vertically above the uppermost position of second portion(s) 112b of base film 112 and its respective silicide layers 144. Such implementations may offer a more compact arrangement of components within bipolar transistor 110 than available in the example configuration of FIG. 1, but with more inter-component electrical isolation than the example configuration of FIG. 2. It is also understood that in still further modifications and/or arrangements of features in structure 100 are possible, beyond those specifically illustrated in FIGS. 1-3.

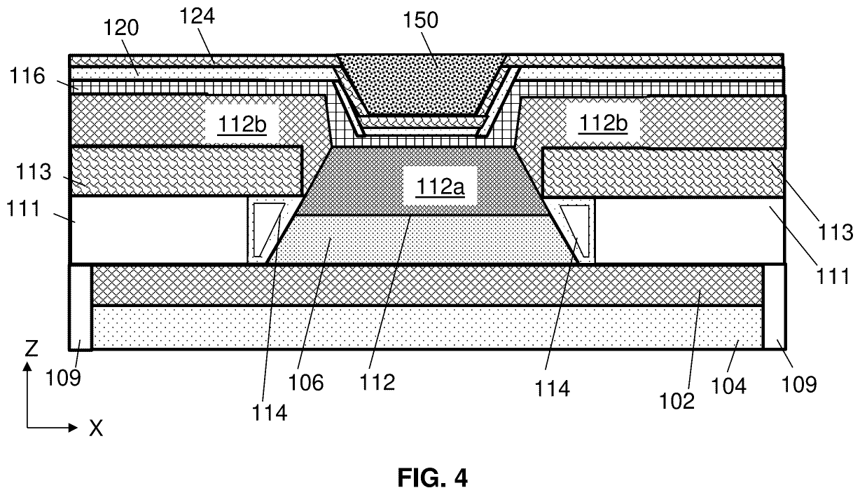

Turning to FIG. 4, the disclosure includes methods to form any configuration of structure(s) 100 (FIGS. 1-3) discussed herein. Initial phases of processing may include forming collector 106, base film 112, semiconductor film 116, and isolation layers 111, 113 according to various operations discussed elsewhere herein regarding structure 100, and/or using any series of conventional or later developed techniques to form adjacent materials. As shown, substrate 104 may have subcollector 102 thereover and various trench isolations 109 may be within substrate 104 adjacent subcollector 102. Collector 106 may be on subcollector 102, between portions of first isolation layer 111, and optionally, corresponding air gaps 114. First portion 112a of base film 112 may be on collector 106 and horizontally between second isolation layer 113. Second portions 112b of base film 112 may be on outer horizontal ends of first portion 112a, adjacent sidewalls of isolation layer 113, and over second isolation layer 113 as discussed herein.

Semiconductor film 116 may extend horizontally over base film 112 and may have a similar shape as base film 112. First spacer liner 120 may be on semiconductor film 116 and second spacer liner 124 may be on first spacer liner 120. Liners 120, 124 initially may have the same geometrical profile as base film 112 and semiconductor film 116 but may be modified in later phases of processing to create electrical couplings between semiconductor film 116 and emitter 118 (FIGS. 1-3). These various layers and materials may be formed by repeated instances of deposition (including non-selective epitaxial growth where applicable, e.g., for base film 112) and etching to yield precursor components, i.e., collector 106 and base film 112 substantially as defined in an eventual bipolar transistor 110 (FIGS. 1-3). Liners 120, 124 may be formed simply by deposition of insulator material, such that they exhibit the shape of semiconductor film 116 thereunder.

FIG. 4 illustrates forming a layer of a patterning layer 150, e.g., a developable bottom anti-reflective coating (DBARC) layer and/or similar patterning material (formable, e.g., by implantation) to enable processing of other materials nearby. Patterning layer 150 may differ from other masking material(s) by extending downward into space between previously formed and/or processed materials, instead of being located on uppermost surfaces of such materials. Patterning layer 150 thus may temporarily protect underlying portions of collector 106, base film 112, semiconductor film 116, and/or other materials from being unintentionally modified.

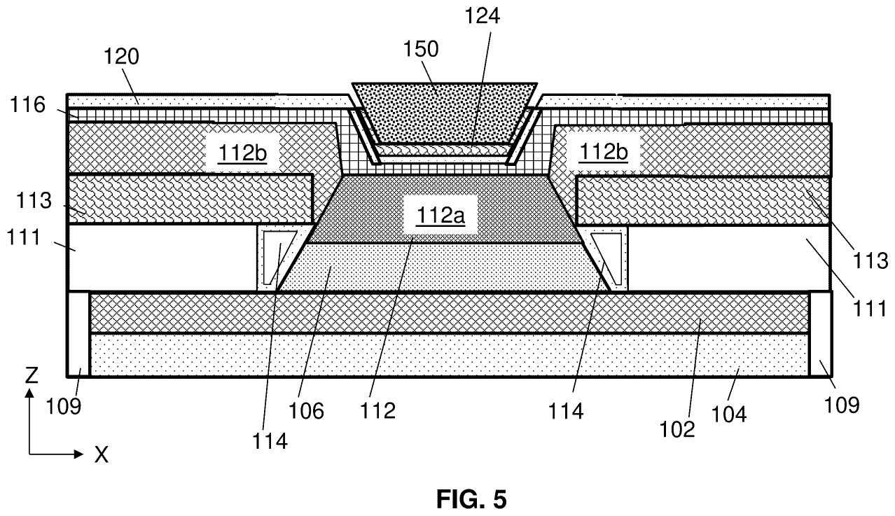

Continuing to FIG. 5, further processing may include partial removing of second spacer liner 124, e.g., by using patterning layer 150 as a mask. The partial removing of second spacer liner 124 may be implemented using one or more etching materials selective to the composition of second spacer liner 124 (e.g., nitride selective etchants) to prevent underlying portions of first spacer liner 120 from being removed. Patterning layer 150 remains intact over collector 106, base film 112, semiconductor film 116, and first spacer liner 120 but portions of second spacer liner 124 not covered by patterning layer 150 are removed. Some portions of second spacer liner 124 located under the horizontal periphery of patterning layer 150 are removed, e.g., due to partial entry and reaction of etchants with these areas of second spacer liner 124. The remainder of second spacer liner 124 may be recessed relative to adjacent portions of first spacer liner 120.

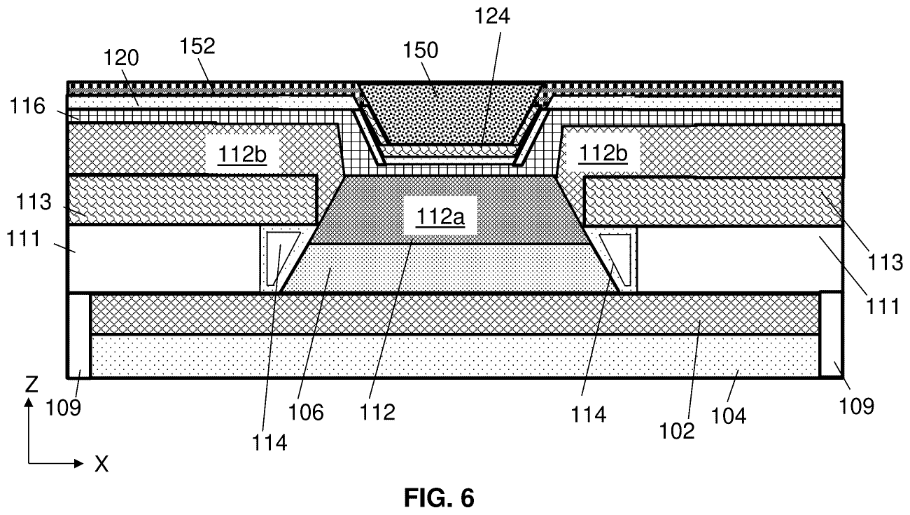

FIG. 6 depicts further processing to enable removal of patterning layer 150. Methods of the disclosure may include forming a photoresist layer 152 on first spacer liner 120 and adjacent patterning layer 150. Photoresist layer 152, initially, may cover patterning layer 150. Photoresist layer 152 may be planarized (e.g., by spin on application) such that photoresist layer 152 is substantially coplanar with patterning layer 150. Photoresist layer 152 may have a different composition from patterning layer 150 to enable selective removal of patterning layer 150 without affecting photoresist layer 152. As shown, portions of photoresist layer 152 may fill the space between patterning layer 150 and first spacer liner 120, previously occupied by portions of second spacer liner 124.

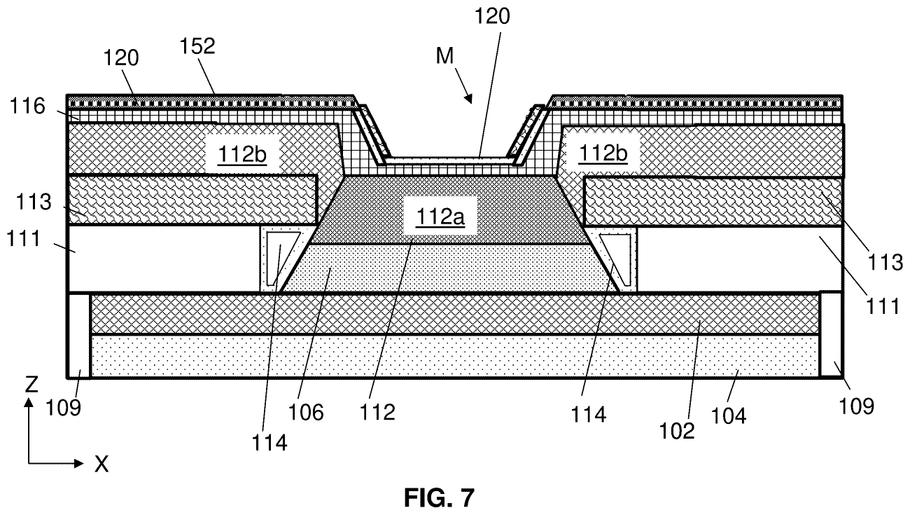

FIG. 7 illustrates subsequent removing of patterning layer 150 (FIGS. 4-6), followed by removing of photoresist layer 152. With photoresist layer 152 in place, patterning layer 150 may be removed by selective etching of patterning layer 150. For example, where patterning layer 150 includes DBARC as discussed herein, any known conventional selective etchants selective to DBARC may remove patterning layer 150. The removing of patterning layer 150 defines a recess M where patterning layer 150 had been present. After removing patterning layer 150, further processing may include downward directional etching (e.g., reactive ion etching (RIE) with materials selective to the composition of second spacer liner 124) to remove portions of spacer liner 124 on the lowermost surface of recess M without significantly affecting or removing any portions of second spacer liner 124 on sidewalls of recess M. Partial removing second spacer liner 124 (e.g., by selective RIE) does not affect first spacer liner 120 or other components on the structure. Additional processing may include, e.g., removing photoresist layer 152 by stripping and/or other currently known or later developed processes for targeted removal of photoresist material of photoresist layer 152.

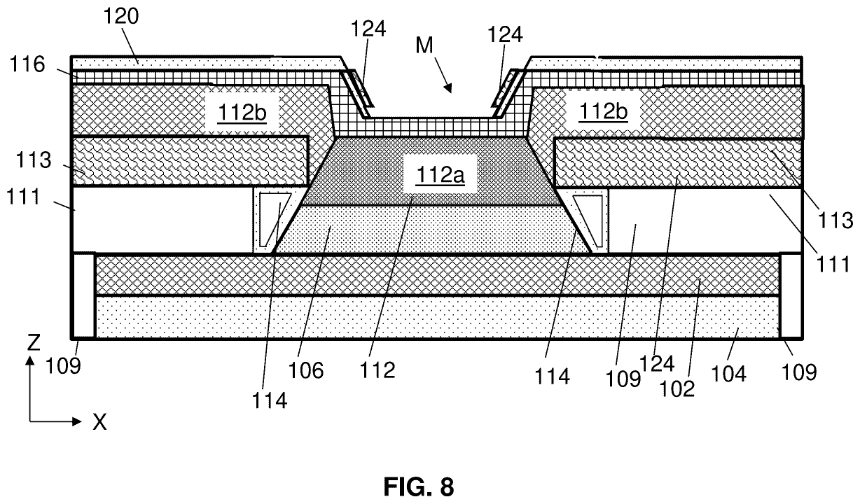

FIG. 8 illustrates still further processing to enable subsequent forming of emitter 118 (FIGS. 1-3) in recess M and in contact with semiconductor film 116. To retain first spacer liner 120 alongside sidewalls of semiconductor film 116, and on uppermost surfaces of semiconductor film 116, portions of first spacer liner 120 located at the bottom of recess M can be targeted and removed, e.g., by additional selective etching techniques. To retain first spacer liner 120 outside recess M, methods of the disclosure can include chemical oxide removal (COR) or similar processes to target first spacer liner 120 only within recess M, such that the removed portions of first spacer liner 120 undercut second spacer liner 124, and second spacer liner 124 protects adjacent portions of first spacer liner 120 from being removed. During this stage of processing, a protective mask (not shown) also may be on first spacer liner 120 outside recess M, before being removed after desired parts of first spacer liner 120 are removed. For example, photoresist layer 152 could function as the protective mask before it is stripped or otherwise removed. At the conclusion of this phase, semiconductor film 116 is exposed within recess M, thus enabling additional active semiconductor material(s) to be formed thereon.

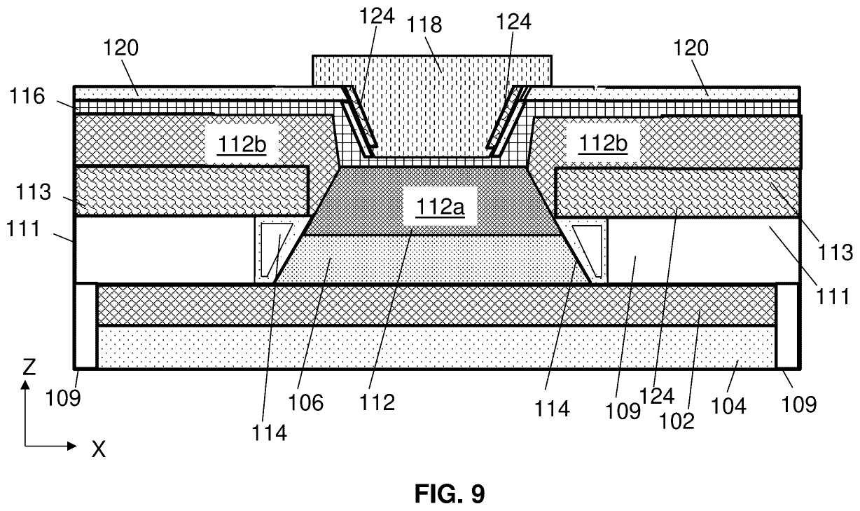

FIG. 9 depicts forming emitter 118 within recess M (FIGS. 7, 8) and on semiconductor film 116. Emitter 118 may have a lowermost surface in contact with semiconductor film 116, but otherwise emitter 118 is separated from semiconductor film 116 by at least first spacer liner 120, and in the case of sidewalls of semiconductor film 116, multiple spacer liners 120, 124. This configuration allows a diode junction of a desired shape and size to be formed along one boundary between semiconductor film 116 and emitter 118. The forming of emitter 118 may include, e.g., forming polycrystalline Si by deposition and/or epitaxial growth, as well as doping emitter 118 to have a desired conductivity type and dopant concentration. In the case of an NPN device, emitter 118 may be doped n-type. In the case of a PNP device, emitter 118 may be doped p-type. Initially, emitter 118 may extend horizontally beyond second spacer liner 124 and over second portions 112b of base film 112. Further processing may include covering emitter 118 with a temporary mask (not shown) having a desired shape and removing any portions of emitter 118 not covered by the temporary mask.

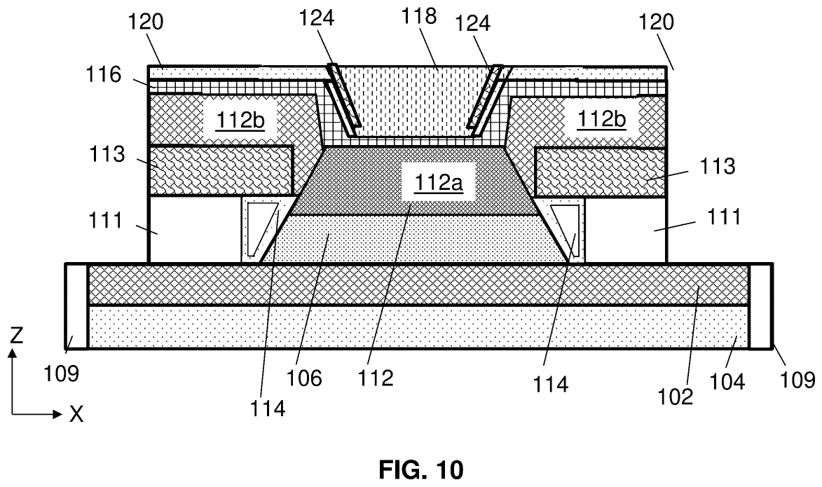

FIG. 10 depicts removing horizontally outer areas of isolation layers 111, 113, base film 112, semiconductor film 116, and first spacer liner 120 to expose subcollector 102 and adjacent trench isolations 109. Removing these outer portions of material may enable subsequent forming of ILD 140 (FIGS. 1-3) over the structure, and processing of ILD 140 to form contacts and silicide layers 144 (FIGS. 1-3) in desired locations. Removing material in these locations may be implemented, e.g., by forming another temporary mask (not shown) over the desired remaining layers of material and removing any non-covered parts of isolation layers 111, 113, base film 112, semiconductor film 116, and first spacer liner 120 by downward etching. Optionally, further processing may include partial or complete planarization of emitter 118 (e.g., as shown in FIG. 10). Alternatively, the planarization and/or recessing of emitter 118 can be omitted (e.g., to produce a larger size emitter as shown in FIG. 1) or by additionally planarizing first spacer liner 120 (e.g., to produce a smaller size emitter as shown in FIG. 2). Regardless of how or whether emitter 118 and first spacer liner 120 are planarized, subsequent processing to form ILD 140 and other features such as contact(s) 142, 146, 148 (FIGS. 1-3) and silicide layer(s) 144 may be implemented regardless of emitter 118 shape and size. Such processing can yield structure 100 bipolar transistor(s) 110 (FIGS. 1-3) according to any configuration or combination of configurations discussed herein.

Embodiments of the disclosure provide various technical and commercial advantages, examples of which are discussed herein. Embodiments of the disclosure are operable to form extrinsic base and intrinsic base materials together, e.g., by one epitaxial growth of semiconductor material (i.e., base film 112) in which different portions of the material have different properties (e.g., first portion 112a is monocrystalline and second portion 112b is polycrystalline). This process thus eliminates the additional deposition passes otherwise required in conventional techniques to form bipolar transistors. Furthermore, the forming of base film 112 is achievable using non-selective epitaxial growth, which is faster and less sensitive than selective epitaxy or other alternative techniques. Notwithstanding these improvements to processing efficiency, the performance of bipolar transistor 110 is electrically preferable to conventional heterojunction bipolar transistors, e.g., due to the self-alignment of emitter 118 with collector 106, base film 112, and semiconductor film 116 and the smaller size of base film 112 compared to conventional intrinsic-extrinsic base assemblies. Bipolar transistor 110 according to embodiments of the disclosure can be scaled to collected widths of varying size due to self-alignment between emitter 118 and active materials (collector 106, base film 112, semiconductor film 116) thereunder. Such performance benefits also arise from the smaller size of bipolar transistor 110 relative to conventional devices. In addition, embodiments of the disclosure prevent undesirable “base link” electrical couplings between extrinsic and intrinsic base materials due to the structure of base film 112 and different crystallographic properties each portion 112a, 112b thereof, despite the unitary chemical composition (e.g., SiGe throughout base film 112).

The method and structure as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about,” “approximately,” and “substantially,” are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s).

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

What is claimed is:

1. A structure comprising:
a semiconductor base film on a collector terminal, the semiconductor base film including:
a first portion within an opening of an isolation layer, the first portion including an intrinsic semiconductor, and
a second portion on the first portion, the second portion including a sidewall adjacent the isolation layer and a lower surface on the isolation layer;
a semiconductor film on an upper surface of the first portion of the isolation layer and adjacent a sidewall of the second portion of the isolation layer; and
an emitter on the semiconductor film.

2. The structure of claim 1, wherein the isolation layer vertically separates the second portion of the semiconductor base film from the collector terminal.

3. The structure of claim 1, further comprising a first spacer liner on a sidewall of the second portion of the semiconductor base film.

4. The structure of claim 3, further comprising a second spacer liner between the first spacer liner and on a sidewall of the emitter, wherein the second spacer liner has a different material composition from the first spacer liner.

5. The structure of claim 1, wherein the first portion of the base film includes a monocrystalline semiconductor and the second portion of the base film includes a polycrystalline semiconductor.

6. The structure of claim 1, wherein a centerline axis of the emitter is substantially vertically aligned with a centerline axis of the opening of the isolation layer.

7. The structure of claim 1, wherein the semiconductor film is substantially U-shaped.

8. A structure comprising:
an isolation stack including a first isolation layer having a first opening and a second isolation layer having a second opening over the first opening, wherein a width of the first opening is larger than a width of the second opening;
a collector terminal on a subcollector and within the first opening of the first isolation layer;
a semiconductor base film on the collector terminal, the semiconductor base film including:
a first portion within the second opening of the second isolation layer, the first portion including an intrinsic semiconductor, and
a second portion on the first portion, the second portion including a sidewall adjacent the isolation layer and a lower surface on the isolation layer;
a semiconductor film on an upper surface of the first portion of the isolation layer and adjacent a sidewall of the second portion of the isolation layer; and
an emitter on the semiconductor film.

9. The structure of claim 8, wherein an air gap is between the collector terminal and the first isolation layer, and wherein the semiconductor base film encapsulates at least the sidewall of the second isolation layer.

10. The structure of claim 8, further comprising a first spacer liner on a sidewall of the second portion of the semiconductor base film.

11. The structure of claim 10, further comprising a second spacer liner between the first spacer liner and on a sidewall of the emitter, wherein the second spacer liner has a different material composition from the first spacer liner.

12. The structure of claim 8, wherein the first portion of the base film includes a monocrystalline semiconductor and the second portion of the base film includes a polycrystalline semiconductor.

13. The structure of claim 8, wherein a centerline axis of the emitter is substantially vertically aligned with a centerline axis of the opening of the isolation layer.

14. The structure of claim 8, wherein the semiconductor film is substantially U-shaped.

15. A method comprising:
forming a semiconductor base film on a collector terminal, the semiconductor base film including:
a first portion within an opening of an isolation layer, the first portion including an intrinsic semiconductor, and
a second portion on the first portion, the second portion including a sidewall adjacent the isolation layer and a lower surface on the isolation layer;
forming a semiconductor film on an upper surface of the first portion of the isolation layer and adjacent a sidewall of the second portion of the isolation layer; and
forming an emitter on the semiconductor film.

16. The method of claim 15, further comprising forming a first spacer liner on a sidewall of the second portion of the semiconductor base film.

17. The method of claim 16, further comprising forming a second spacer liner between the first spacer liner and on a sidewall of the emitter, wherein the second spacer liner has a different material composition from the first spacer liner.

18. The method of claim 15, wherein the first portion of the base film includes a monocrystalline semiconductor and the second portion of the base film includes a polycrystalline semiconductor.

19. The method of claim 15, wherein a centerline axis of the emitter is substantially vertically aligned with a centerline axis of the opening of the isolation layer.

20. The method of claim 15, wherein the semiconductor film is substantially U-shaped.
